(19) United States
(12) Patent Application Publication
(10) Pub. No.: US 2008/0230798 A1
(43) Pub. Date: Sep. 25, 2008

(54) ACTIVE MATRIX ORGANIC ELECTROLUMINESCENT SUBSTRATE AND METHOD OF MAKING THE SAME

(76) Inventors: Shu-Hui Huang, Hsin-Chu (TW); Hsiao-Wei Yeh, Hsin-Chu (TW); Min-Ling Hung, Hsin-Chu (TW); Hsia-Tsai Hsiao, Hsin-Chu (TW)

Correspondence Address: NORTH AMERICA INTELLECTUAL PROPERTY CORPORATION, P.O. BOX 506, MERRIFIELD, VA, 22116, US

(21) Appl. No.: 11/751,616

(22) Filed: May 21, 2007

(30) Foreign Application Priority Data
Mar. 21, 2007 (TW) 096109731

(51) Int. Cl. H01L 21/02; H01L 21/027; H01L 33/00

(52) U.S. Cl. 257/99; 438/23; 257/E29.327; 257/E21.04

(57) ABSTRACT

An active matrix organic electroluminescent substrate includes a substrate having a controlling element region and a luminescent region, a thin film transistor, a first passivation layer, a conductive layer electrically connected to the thin film transistor, and a second passivation layer disposed on the first passivation layer and the conductive layer. The second passivation layer has an opening partially exposing the conductive layer, and a step-shaped structure located between the controlling element region and the luminescent region.

### BACKGROUND OF THE INVENTION

1. Field of the Invention

The present invention relates to an organic electroluminescent substrate and a method of making the same, and more particularly, to an organic electroluminescent substrate whose passivation layer has a step-shaped structure located between a controlling element region and a luminescent region and the method of making the same.

2. Description of the Prior Art

Flat displays have advantages of saving electricity, low radiation, and small size over the traditional cathode ray tube (CRT) displays. For these reasons, flat displays are replacing CRT displays gradually. With the improvements of flat display techniques, the price of flat displays is getting lower. Therefore, flat displays are more popular and undergoing developments for larger sizes. Because of having the advantages of high contrast and self-luminosity, the organic electroluminescence display is a most remarkable product among the flat displays at present.

Please refer to FIG. 1. FIG. 1 is a cross-sectional schematic diagram illustrating a conventional organic electroluminescent substrate 10. As shown in FIG. 1, the conventional organic electroluminescent substrate 10 includes a substrate 12 divided into a controlling element region 14 and a luminescent region 16. A thin film transistor 18 is disposed in the controlling element region 14, and the thin film transistor 18 in the controlling element region and the luminescent region 16 is covered with a first passivation layer 20. In addition, the surface of the first passivation layer 20 in the luminescent region 16 has a conductive layer 22 thereon, and the conductive layer 22 is electrically connected to the thin film transistor 18 through an opening 24 in the first passivation layer 20. There is a second passivation layer 26 formed on the surfaces of the first passivation layer 20 and the conductive layer 22. The second passivation layer 26 in the luminescent region 16 has an opening 28, and the opening 28 partially exposes the conductive layer 22. Furthermore, there are an organic luminescent layer 30 and an electrode layer 32 formed on the surface of the conductive layer 22.

### SUMMARY OF THE INVENTION

It is therefore an object of the present invention to provide an active matrix organic electroluminescent substrate so as to raise the display effect.

It is therefore another object of the present invention to provide a method of making the active matrix organic electroluminescent substrate.

According to the claimed invention, an active matrix organic electroluminescent substrate is disclosed. The active matrix organic electroluminescent substrate comprises a substrate having a controlling element region and a luminescent region. A thin film transistor is disposed in the controlling element region of the substrate. A first passivation layer is then disposed in the controlling element region and the luminescent region and covering the thin film transistor. A conductive layer electrically connected to the thin film transistor is disposed on the first passivation layer in the luminescent region and in a part of the controlling element region. A second passivation layer is disposed on the first passivation layer and the conductive layer, the second passivation layer having an opening in the luminescent region partially exposing the conductive layer and a step-shaped structure located between the controlling element region and the luminescent region.

Also according to the claimed invention, a method of making an active matrix organic electroluminescent substrate is disclosed. The method comprises providing a substrate and defining a controlling element region and a luminescent region on the substrate. A first passivation layer is formed on the substrate in the controlling element region and in the luminescent region. A conductive layer is then formed on a part of the first passivation layer. A second passivation layer is formed on the first passivation layer and the conductive layer. The second passivation layer in the luminescent layer is removed to form an opening partially exposing the conductive layer and a part of the second passivation layer near the opening is removed to make the second passivation layer have a step-shaped structure located between the controlling element region and the luminescent region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional schematic diagram illustrating a conventional organic electroluminescent substrate.

FIG. 2 through FIG. 8 are schematic diagrams illustrating a method of making an active matrix organic electroluminescent substrate according to a preferred embodiment of the present invention.

FIG. 9 is a schematic diagram illustrating a method of making an active matrix organic electroluminescent substrate according to another preferred embodiment of the present invention.

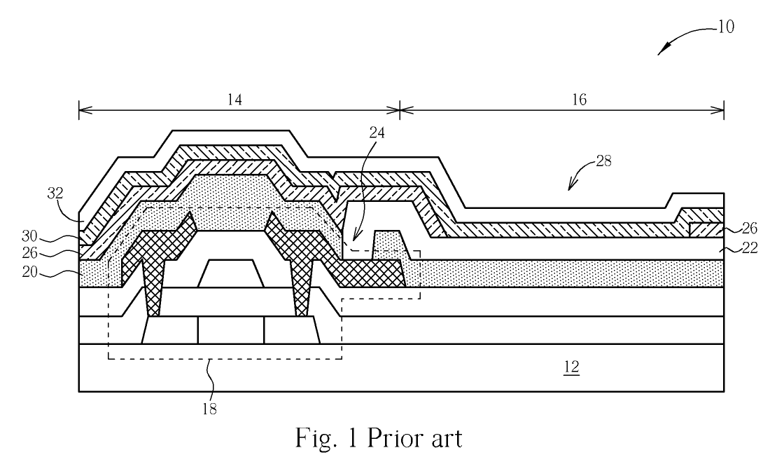

### DETAILED DESCRIPTION

The angle of the second passivation layer 26 of the conventional organic electroluminescent substrate 10 located between the controlling element region 14 and the luminescent region 16 is overly large so that a thickness difference between the thickness of the organic luminescent layer 30 on the inclined surface of the second passivation layer 26 and on the flat surface will be overly large. The thickness difference may make the conventional organic electroluminescent substrate 10 have a problem of light leakage between the controlling element region 14 and the luminescent region 16. In addition, the second passivation layer 26 of the conventional organic electroluminescent substrate 10 is an inorganic material, such as silicon oxide or silicon nitride. The thickness limitation of the second passivation layer 26 constituted by the inorganic material is 3000 Å because of manufacturing concerns, such as processing time, etc. The insufficient thickness of the second passivation layer 26 will make a mask used for defining the organic electroluminescent layer 30 in the evaporation process compress the original structure in the luminescent region 16 during subsequent evaporation of the organic luminescent layer 30. Therefore, the structure in the luminescent region 16 may be damaged and produce more particles so that the luminescent efficiency is bad.

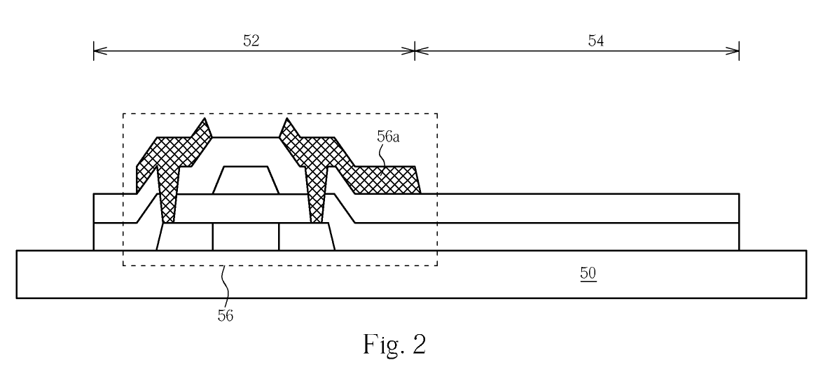

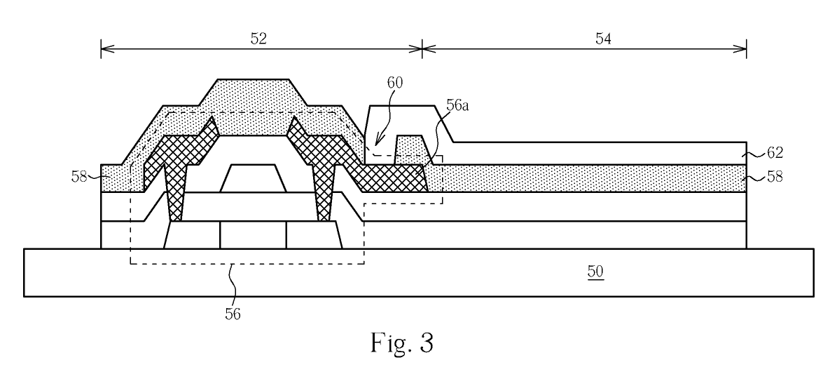

Please refer to FIG. 2 through FIG. 8. FIG. 2 through FIG. 8 are schematic diagrams illustrating a method of making an active matrix organic electroluminescent substrate according to a preferred embodiment of the present invention. As shown in FIG. 2, first, a substrate 50, such as a glass substrate, a plastic substrate or a quartz substrate, is provided. The substrate 50 is divided into a controlling element region 52 and a luminescent region 54. Next, a thin film transistor (TFT) 56 is formed in the controlling element region 52 of the substrate 50, wherein the thin film transistor 56 can be amorphous silicon thin film transistor, low temperature poly-silicon (LTPS) thin film transistor or high temperature poly-silicon thin film transistor, etc. The step of fabricating the thin film transistor 56 is well known in the industry, so the step will not be described redundantly. As shown FIG. 3, subsequently, a first passivation layer 58 is formed in the controlling element region 52 and in the luminescent region 54 of the substrate 50, and an opening 60 is formed in the area of the first passivation layer 58 corresponding to the thin film transistor 56 so as to partially expose the drain 56a of the thin film transistor 56. Next, a conductive layer 62 is formed on a part of the first passivation layer 58, and the conductive layer 62 is electrically connected to the drain 56a of the thin film transistor 56 through the opening 60. The conductive layer 62 can be an anode of the active matrix organic electroluminescent substrate of the present invention, and the material of the conductive layer 62 can be decided according to the display type of the active matrix organic electroluminescent substrate. For example, if a bottom emission type of the organic electroluminescent substrate is required, the material of the conductive layer 62 should be the transparent conductive material, such as indium-tin oxide (ITO), indium-zinc oxide (IZO) or a combination thereof. If a top emission type of the organic electroluminescent substrate is required, the material of the conductive layer 62 should be metal, such as aluminum, silver or a combination thereof.

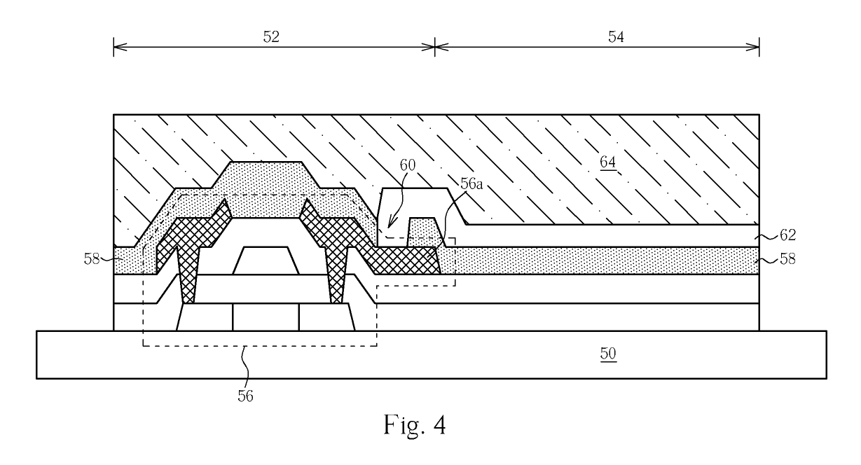

As shown in FIG. 4, a second passivation layer 64 is formed on the first passivation layer 58 and the conductive layer 62. In this embodiment, the second passivation layer 64 is an organic material, such as polyimide resin, acrylic resin or organic silica, etc. The advantage of using the organic material is that the above-mentioned organic material can be applied using the coating method, such as spin-coating method. Compared with the step of fabricating the passivation layer with evaporating process of the prior art, this embodiment can save more processing time and raise the thickness limitation of the second passivation layer 64. In this embodiment, the thickness of the second passivation layer 64 is substantially 3 μm to 5 μm but not limited thereto. In addition, the organic material of this embodiment can be patterned by directly using exposing technology after adding photosensitive material so that the etching process may be no longer needed.

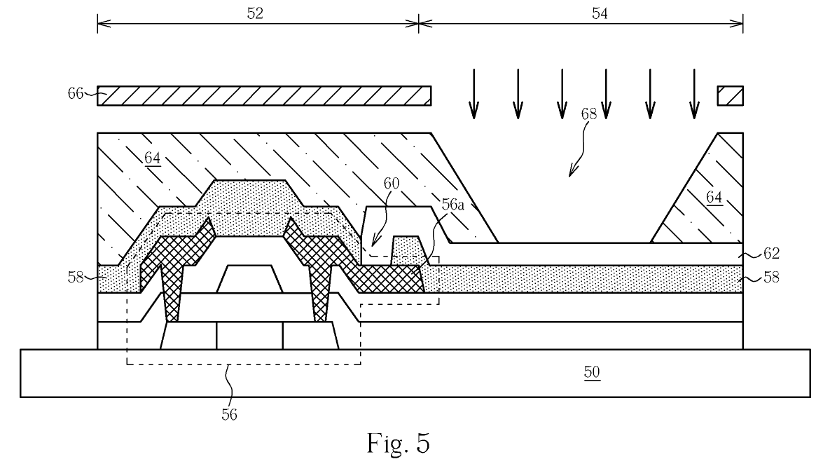

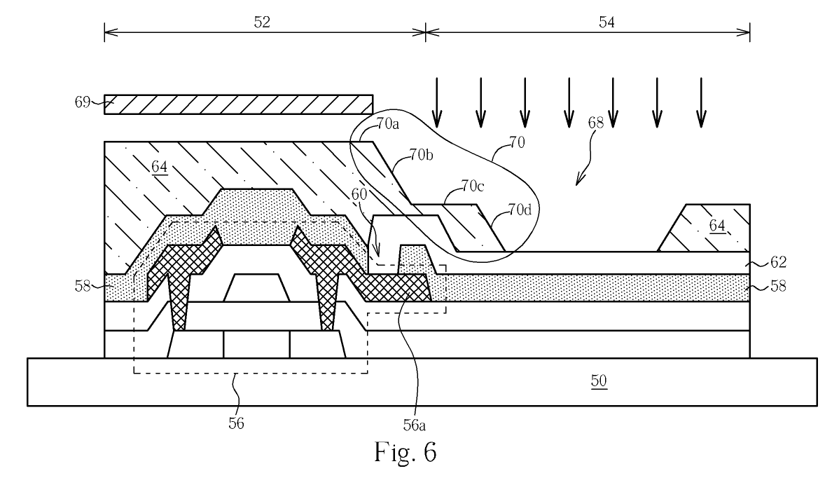

Next, a two-stage exposing process is performed. As shown in FIG. 5, first, a first exposing process is performed with a first mask 66 to remove a part of the second passivation layer 64 in the luminescent region 54 so as to form an opening 68. As shown in FIG. 6, then, a second exposing process is performed with a second mask 69 to remove a part of the second passivation layer 64 near the opening 68 so as to form a step-shaped structure 70 located between the controlling element region 52 and the luminescent region 54. The object of the two-stage exposing process is to make the second passivation layer 64 have the step-shaped structure 70. In the first exposing process, the opening 68 needs to have a deeper depth, so the exposing energy should be higher. In the second exposing process, the thickness of the second passivation layer 64 needs to be shallower, so the exposing energy of the second exposing process should be lower than that of the first exposing process. The exposing energy difference between the first exposing process and the second exposing process is about 10 millijoule (mj) to 60 mj, but the exposing energy of the two-stage exposing process can be modulated according to the thickness of the second passivation layer 64, not limited to the above-mentioned.

In this embodiment, the step-shaped structure 70 of the second passivation layer 64 has a first flat surface 70a, a first inclined surface 70b, a second flat surface 70c and a second inclined surface 70d. The height difference between the first flat surface 70a and the surface of the conductive layer 62 is about 3 μm to 5 μm; that is also the thickness of the second passivation layer 64. The height difference between the second flat surface 70c and the surface of the conductive layer 62 is about 3000 Å to 2 μm. In addition, the second inclined surface 70d and the surface of the conductive layer 62 form an included angle, and the angle is about 10 degrees to 40 degrees. It is worthy to be noted that the included angle between the second inclined surface 70d and the conductive layer 62 not only has a relationship with the exposing energy but also with the adhesion between the second passivation layer 64 and the conductive layer 62. Therefore, adjusting the parameters, such as the element or viscosity of the second passivation layer 64, combined with the appropriate exposing energy, can accurately control the included angle.

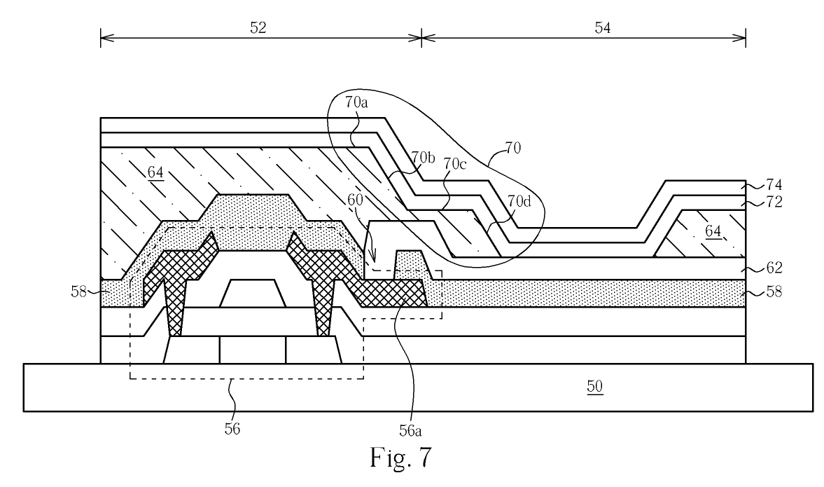

As shown in FIG. 7, next, an organic luminescent layer 72 and an electrode layer 74 are formed in turn on the conductive layer 62 and the second passivation layer 64. The material of the organic luminescent layer 72 can be different, and the organic material can be decided according to the pixel color required to display, such as red light organic emitting material, green light organic emitting material, blue light organic emitting material or white light organic emitting material. The electrode layer 74 is a cathode of the organic electroluminescent substrate, and the material of the electrode layer 74 can be a transparent conductive material or conductive metal according to the type of the active matrix organic electroluminescent substrate. The step-shaped structure 70 of the second passivation layer 64 makes the thickness difference in the vertical direction of the organic luminescent layer 72 located between the controlling element region 52 and the luminescent region 54 smaller so that the problem of light leakage can be avoided. In addition, the thickness of the second passivation layer 64 can prevent the luminescent region 54 from being damaged by the mask used in fabricating the organic luminescent layer 72.

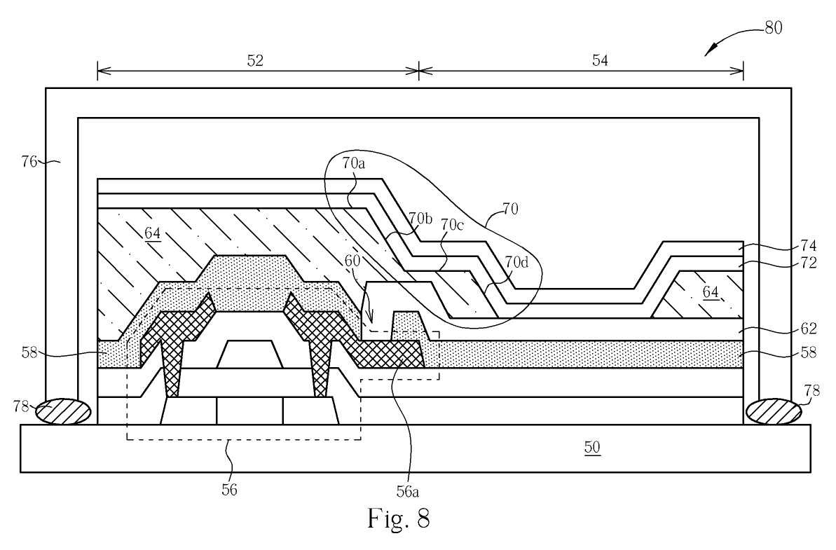

According to the above-mentioned process, the active matrix organic electroluminescent substrate of the present invention can be completed, and the substrate is the bottom substrate of the active matrix organic electroluminescent substrate. If an active matrix organic electroluminescent panel is required, the following process needs to be performed. As shown in FIG. 8, a cap 76 is provided, such as a glass cap. The cap 76 is sealed to the substrate 50 of the active matrix organic electroluminescent substrate with sealant 78, so the active matrix organic electroluminescent panel 80 is completed.

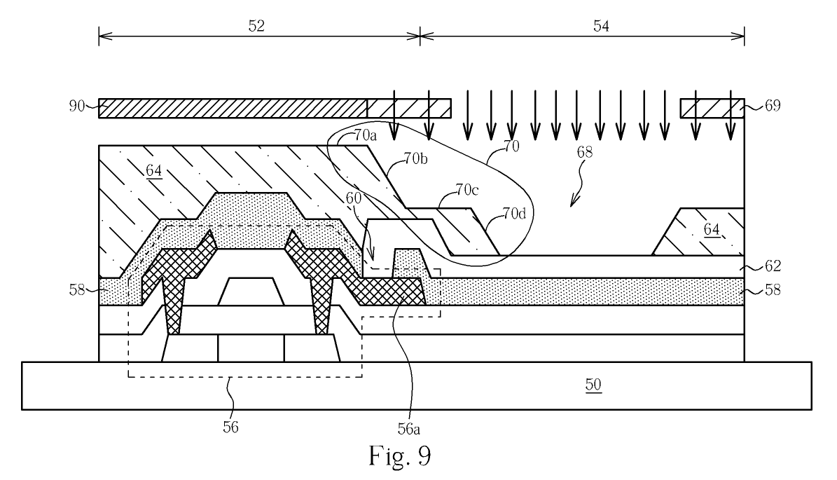

The step-shaped structure 70 of the above-mentioned embodiment is fabricated by using the two-stage exposing process. However, the fabricating method of the present invention is not limited to this, and the step-shaped structure 70 can be fabricated by using the greytone mask or the halftone mask. Please refer to FIG. 9. FIG. 9 is a schematic diagram illustrating a method of making an active matrix organic electroluminescent substrate according to another preferred embodiment of the present invention. In order to compare the difference between the two embodiments of the present invention more easily, like devices use the same reference mark. The step of this embodiment starts after FIG. 4, and like steps will not be detailed redundantly. As shown in FIG. 9, an exposing process is performed with a halftone mask 90, and the mask can control the aperture ratio in light exposing so that different exposing energy can be adjusted in different positions. The area predetermined to form the opening 68 can have higher exposing energy, and the area predetermined to form the step-shaped structure 70 has lower exposing energy. Therefore, although only single exposing process is performed, the opening 68 and the step-shaped structure 70 located between the controlling element region 52 and the luminescent region 54 can be formed together.

According to the above-mentioned, the present invention uses the organic material having photosensitivity to be the second passivation layer so as to effectively raise the thickness limitation of the second passivation layer and prevent the structure in the luminescent region from being damaged. The step-shaped structure of the second passivation layer can avoid the problem of light leakage so that the organic electroluminescent panel can normally display.

Those skilled in the art will readily observe that numerous modifications and alterations of the device and method may be made while retaining the teachings of the invention.

What is claimed is:

1. An active matrix organic electroluminescent substrate, comprising:
a substrate having a controlling element region and a luminescent region;
a thin film transistor disposed in the controlling element region of the substrate;
a first passivation layer disposed in the controlling element region and the luminescent region and substantially covering the thin film transistor;
a conductive layer electrically connected to the thin film transistor, disposed on the first passivation layer in the luminescent region and in a part of the controlling element region; and
a second passivation layer disposed on the first passivation layer and the conductive layer, the second passivation layer having an opening in the luminescent region partially exposing the conductive layer and a step-shaped structure located between the controlling element region and the luminescent region.

2. The active matrix organic electroluminescent substrate of claim 1, wherein the material of the conductive layer comprises indium-tin oxide, indium-zinc oxide, aluminum, silver or a combination thereof.

3. The active matrix organic electroluminescent substrate of claim 1, wherein the second passivation layer comprises an organic material.

4. The active matrix organic electroluminescent substrate of claim 3, wherein the organic material comprises polyimide resin, acrylic resin, organic silica or a combination thereof.

5. The active matrix organic electroluminescent substrate of claim 1, further comprising an organic luminescent layer covering the conductive layer, and an electrode layer disposed on the organic luminescent layer.

6. The active matrix organic electroluminescent substrate of claim 5, wherein the organic luminescent layer substantially covers the second passivation layer.

7. The active matrix organic electroluminescent substrate of claim 1, wherein the step-shaped structure of the second passivation layer has a first flat surface, a first inclined surface, a second flat surface and a second inclined surface.

8. The active matrix organic electroluminescent substrate of claim 7, wherein a height difference between the second flat surface and a surface of the conductive layer is substantially 3000 Å to 2 μm.

9. The active matrix organic electroluminescent substrate of claim 7, wherein a height difference between the first flat surface and a surface of the conductive layer is substantially 3 μm to 5 μm.

10. The active matrix organic electroluminescent substrate of claim 7, wherein the second inclined surface and a surface of the conductive layer form an included angle, and the included angle is substantially 10 degrees to 40 degrees.

11. An active matrix organic electroluminescent panel, comprising:
an active matrix organic electroluminescent substrate of claim 1; and
a cap sealed with the active matrix organic electroluminescent substrate.

12. A method of making an active matrix organic electroluminescent substrate, comprising:
providing a substrate having a controlling element region and a luminescent region;
forming a first passivation layer on the substrate;
forming a conductive layer on a part of the first passivation layer;
forming a second passivation layer on the first passivation layer and the conductive layer; and
removing the second passivation layer in the luminescent layer to form an opening partially exposing the conductive layer and removing a part of the second passivation layer near the opening to make the second passivation layer have a step-shaped structure located between the controlling element region and the luminescent region.

13. The method of claim 12, wherein the step-shaped structure of the second passivation layer has a first flat surface, a first inclined surface, a second flat surface and a second inclined surface.

14. The method of claim 13, wherein a height difference between the first flat surface and a surface of the conductive layer is substantially 3 μm to 5 μm.

15. The method of claim 13, wherein a height difference between the second flat surface and a surface of the conductive layer is substantially 3000 Å to 2 μm.

16. The method of claim 13, wherein the second inclined surface and a surface of the conductive layer form an included angle, and the included angle is substantially 10 degrees to 40 degrees.

17. The method of claim 12, wherein the second passivation layer is formed by a spin-coating method.

18. The method of claim 12, wherein a step of forming the opening and the step-shaped structure comprises:
performing a first exposing process with a first mask to remove a part of the second passivation layer in the luminescent region so as to form the opening; and
performing a second exposing process with a second mask to remove a part of the second passivation layer near the opening so as to form the step-shaped structure located between the controlling element region and the luminescent region.

19. The method of claim 18, wherein the exposing energy of the first exposing process is higher than the exposing energy of the second exposing process.

20. The method of claim 19, wherein the exposing energy difference between the first exposing process and the second exposing process is 10 mj to 60 mj.

21. The method of claim 12, wherein a step of forming the opening and the step-shaped structure comprises:
performing an exposing process with a halftone mask to form the opening and forming the step-shaped structure located between the controlling element region and the luminescent region.
